(19) United States
(12) Patent Application Publication
(10) Pub. No.: US 2009/0229653 A1
(43) Pub. Date: Sep. 17, 2009

(54) STACKED-LAYERED THIN FILM SOLAR CELL AND MANUFACTURING METHOD THEREOF

(76) Inventors: Chun-Hsiung Lu, Houli Township (TW); Chien-Chung Bi, Houli Township (TW)

Correspondence Address: SINORICA, LLC, 2275 Research Blvd., Suite 500, ROCKVILLE, MD, 20850, US

(21) Appl. No.: 12/180,574

(22) Filed: Jul. 28, 2008

(30) Foreign Application Priority Data
Mar. 13, 2008 (TW) 097108812

(51) Int. Cl. H01L 31/042; H01L 21/00

(52) U.S. Cl. 136/249; 438/73; 257/E27.005

(57) ABSTRACT

This invention discloses a stacked-layered thin film solar cell and a manufacturing method thereof. The stacked-layered thin film solar cell with a plurality of unit cells comprises a substrate, a first electrode layer, a first photoconductive layer, an interlayer, a second photoconductive layer, and a second electrode layer in a series stacked structure. It is characterized in that a first isolation groove and a second isolation groove are formed on borders of the second electrode layer and are extending downward to remove the first photoconductive layer. The first isolation groove is parallel with the unit cells and vertical to the second isolation groove. At least one outer groove is formed on the first electrode layer inside the first isolation groove and the second isolation groove, and at least one cutting groove inside the first isolation groove is formed on the interlayer.

### BACKGROUND OF THE INVENTION

1. Technical Field

The present invention relates to a stacked-layered thin film solar cell and a manufacturing method thereof. More particularly, the present invention relates to a stacked-layered thin film solar cell and a manufacturing method thereof wherein an outer groove and a cutting groove are implemented to prevent short-circuit faults.

2. Description of Related Art

Please refer to FIGS. 1A and 1B for a conventional stacked-layered thin film solar cell 1, which comprises a substrate 14, a first electrode layer 11, a semi-conductor layer 13, and a second electrode layer 12 in a series stacked structure. In a manufacturing process of such stacked-layered thin film solar cell 1, the substrate 14 is firstly deposited with the first electrode layer 11 and then receives a laser scribing treatment so as to form a plurality of unit cells 112 and first grooves 111. Then the first electrode layer 11 is deposited thereon with the semi-conductor layer 13, and the semi-conductor layer 13 is such laser scribed that each semi-conductor scribed groove 131 is distant from a said scribed groove of the first electrode layer 11 for about 100 microns. Afterward, the semi-conductor layer 13 is deposited thereon with a second electrode layer 12, and the second electrode layer 12 as well as the semi-conductor layer 13 are such laser scribed that each resultant scribed groove 121 is distant from a said semi-conductor scribed groove 131 for about 100 microns. By the foregoing deposited layers and laser scribing processes performed on each said layer, the stacked-layered thin film solar cell 1 composed of the unit cells 112 in serial is so established.

In a following packaging process, for eliminating problems about short-circuit faults and electric leakage, U.S. Pat. No. 6,300,556 proposes a method involving forming an isolation groove 15 by scribing the solar cell near a periphery thereof for partially removing the first electrode layer, the semi-conductor layer and the second electrode layer, and the mechanically removing the first electrode layer, the semi-conductor layer and the second electrode layer or films of the three layers outside the isolation groove 15 near a periphery of the substrate. Besides, the disclosure of U.S. Pat. No. 6,271,053 involves depositing the layers, dividing the deposited layers into serially connected solar cells, removing the second electrode layer and semi-conductor layer at peripheries of the cells so as to reveal the semi-conductor layer, and then thermally processing the revealed semi-conductor layer to oxidize its surface and thereby increase its resistance. Otherwise, US Patent Publication 2006/0,266,409 reveals the first electrode layer by removing the second electrode layer and the semi-conductor layer with a first laser before using a second laser to remove the second electrode layer, the semi-conductor layer and the first electrode layer elsewhere has been removed by the first laser.

In the above technology, for forming the isolation grooves, due to diverseness of the films, the first laser of a certain wavelength is used to remove the second electrode layer and the semi-conductor layer so as to form scribed grooves, and to repeatedly scribe the scribed isolation grooves to widen the same in order to enhance accurateness of a cutting process later performed on the first electrode layer. Afterward, the second laser of another wavelength is employed to cut the first electrode layer. Since the isolation grooves are formed by two types of laser beams of different wavelengths, the manufacturing procedures are complicated and therefore equipment costs as well as manufacturing cycle are enlarged. Furthermore, after the cutting process is performed, due to possible unevenness of the laser beams, part of the second electrode layer may be not fully removed and, in its melt state, remains on the first electrode layer, leading to short-circuit faults. Though using a single type of laser in length to process the three layers facilitates simplifying the manufacturing procedures, it is notable that the resultant thermal effect is greater and thus the induced short-circuit problem is more significant. Moreover, when thermal treatment is implemented at the late stage of the manufacturing procedures to oxidize the semi-conductor layer and thereby increase its resistance for averting the short-circuit problem, equipment costs and manufacturing cycle can be accordingly increased.

On the other hand, due to recombination of electrons and holes and loss of light, photoelectric conversion efficiency in a stacked-layered thin film solar cell is limited. Thus, an interlayer is usually arranged between a material of a higher energy level and another material of a lower energy level so that when light passes through the stacked-layered thin film solar cell, a portion of the light having short wavelengths that can be absorbed by the material of the higher energy level is reflected to extend a light path while a portion of the light having long wavelengths that can not be absorbed by the material of the higher energy level is led to the material of the lower energy level so as to improve light transmission. For example, U.S. Pat. No. 5,021,100 proposes a dielectric selective reflection film in a stacked-layered thin film solar cell. Since the interlayer, for connecting materials of different energy levels, possesses electric conductivity, electric leakage and short-circuit faults can easily happen during an edge isolating process of the interlayer. Therefore, U.S. Pat. No. 6,632,993 further provides cutting grooves 161 scribed on the interlayer 16 for eliminating electric leakage when a current passes through the interlayer 16, as shown in FIG. 1C. U.S. Pat. No. 6,870,088 also suggests a similar approach but further provides scribed grooves 181 on a photoelectric conversion layer 18 between cutting grooves 171, as shown in FIG. 1D, so as to eliminate the above-mentioned problems. However, all of theses conventional approaches fail to address solutions to short-circuit faults at the edge of the battery.

### SUMMARY OF THE INVENTION

In view of the defects of the conventional devices, the present invention provides a stacked-layered thin film solar cell and a manufacturing method thereof. The stacked-layered thin film solar cell with a plurality of unit cells comprises a substrate, a first electrode layer, a first photoconductive layer, an interlayer, a second photoconductive layer, and a second electrode layer in a series stacked structure. It is characterized in that a first isolation groove and a second isolation groove are formed on at least two borders of the second electrode layer. The first isolation groove and the second isolation groove are outside a projection zone of the unit cells and extending downward to remove the first photoconductive layer. The first isolation groove is parallel with the unit cells and vertical to the second isolation groove. At least one outer groove is formed on the first electrode layer inside the first isolation groove and the second isolation groove, and at least one cutting groove inside the first isolation groove is formed on the interlayer.

Hence, a primary objective of the present invention is to provide a stacked-layered thin film solar cell, which has a cutting groove and isolation grooves at borders thereof, so as to achieve improved isolating efficiency.

A secondary objective of the present invention is to provide a manufacturing method of a stacked-layered thin film solar cell, wherein the stacked-layered thin film solar cell has a cutting groove and isolation grooves at borders thereof, so as to achieve improved isolating efficiency.

### BRIEF DESCRIPTION OF THE DRAWINGS

The invention as well as a preferred mode of use, further objectives and advantages thereof, will best be understood by reference to the following detailed description of an illustrative embodiment when read in conjunction with the accompanying drawings, wherein:

FIGS. 1A and 1B are schematic drawings showing a conventional stacked-layered thin film solar cell;

FIG. 1C is a schematic drawing showing another conventional stacked-layered thin film solar cell;

FIG. 1D is a schematic drawing showing yet another conventional stacked-layered thin film solar cell; and

FIGS. 2A through 2C are schematic drawings showing a stacked-layered thin film solar cell according to a first preferred embodiment of the present invention.

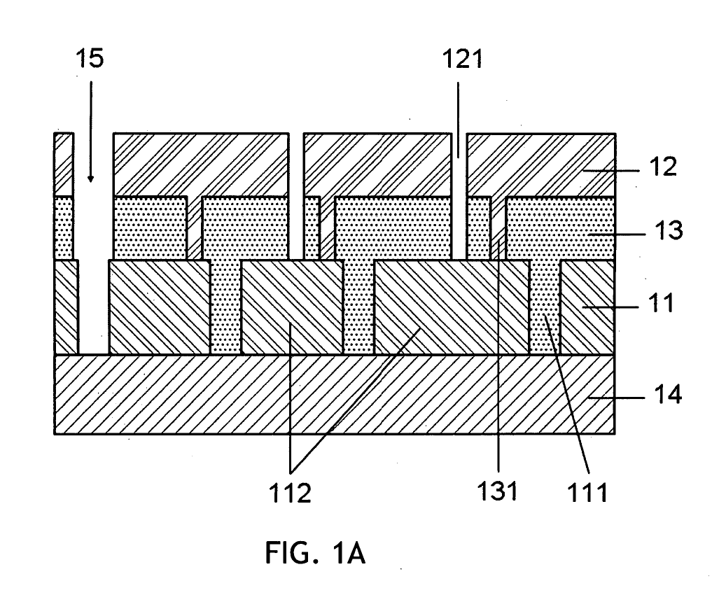

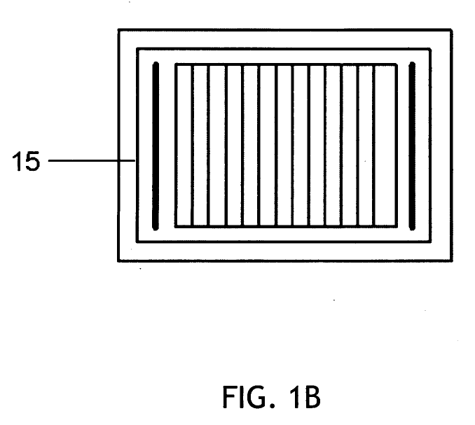

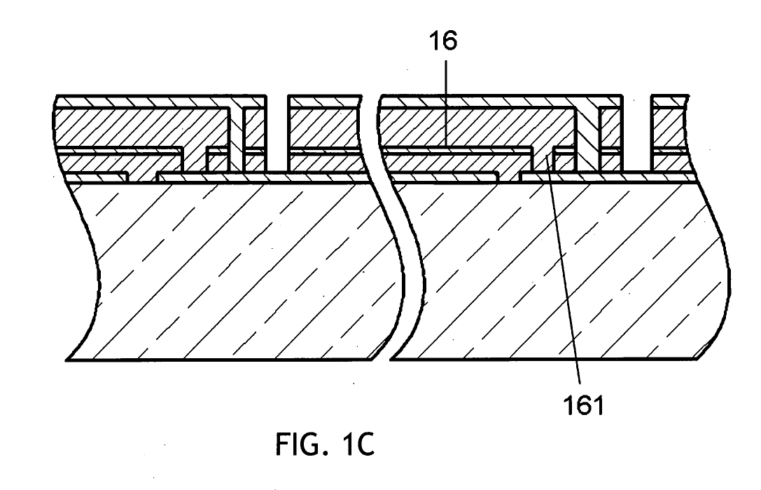

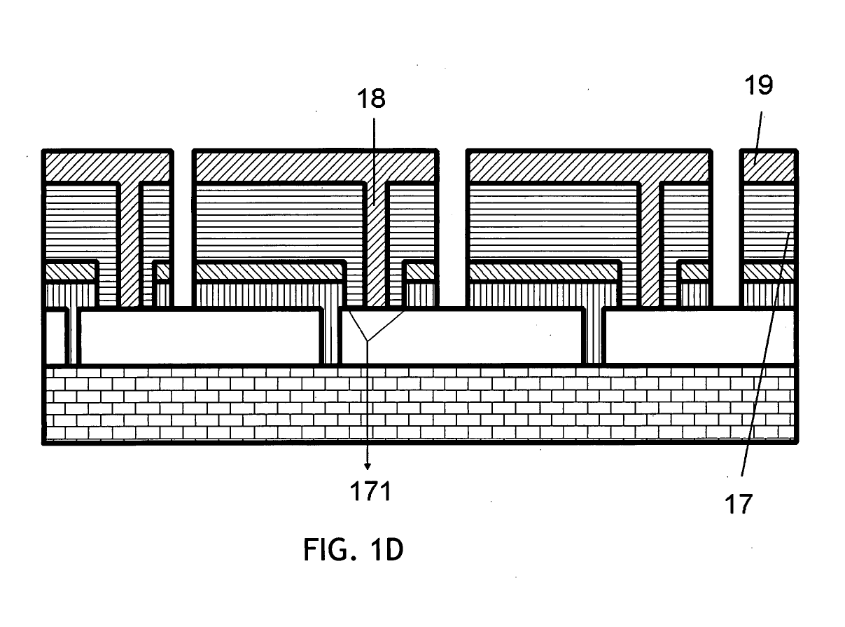

### DETAILED DESCRIPTION OF THE PREFERRED EMBODIMENT

While the present invention discloses a stacked-layered thin film solar cell and a manufacturing method thereof, those skilled in the art will recognize and appreciate that the principle of solar photoelectric conversion implemented therein is well known and need not be discussed at any length herein. Meantime, the accompanying drawings for being read in conjunction with the following descriptions are aim to express features of the present invention and need not to be made in scale.

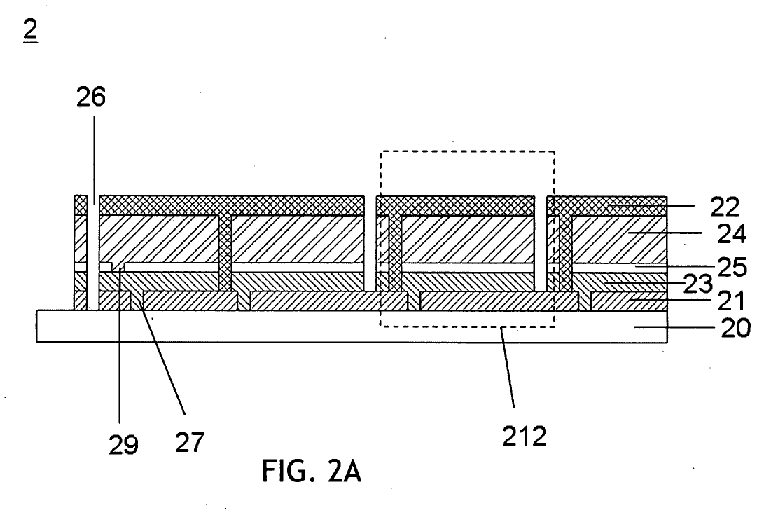

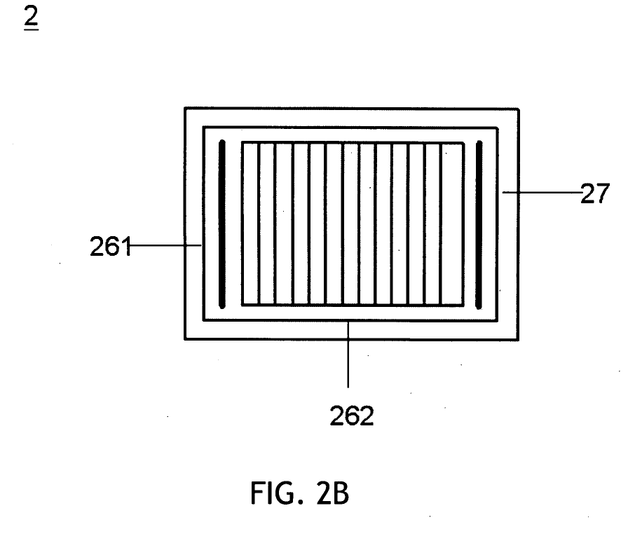

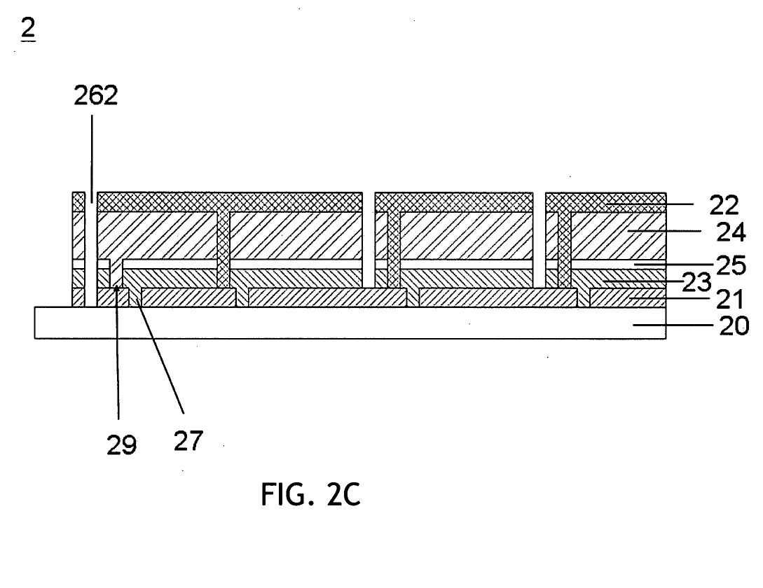

Please refer to FIGS. 2A through 2C for a first preferred embodiment of the present invention. Therein, a stacked-layered thin film solar cell 2 with a plurality of unit cells 212 comprises a substrate 20, a first electrode layer 21, a first photoconductive layer 23, an interlayer 25, a second photoconductive layer 24, and a second electrode layer 22 in a series stacked structure.

The unit cells 212 may be electrically connected in series connection, in parallel connection or in series-parallel connection. Besides, the substrate 20 may be made of a transparent material.

For enhancing edge isolation of the battery so as to eliminate the short-circuit problem, referring to FIG. 2A, a first isolation groove 261 and a second isolation groove 262 are formed on at least two borders of the second electrode layer 22. The first isolation groove 261 and the second isolation groove 262 are outside a projection zone of the unit cells 212 and extending downward to remove the first photoconductive layer 23. Alternatively, the first isolation groove 261 and the second isolation groove 262 can extend downward further to remove the first electrode layer 21, as shown in FIG. 2C. Therein, the first isolation groove 261 is parallel with the unit cells 212 and vertical to the second isolation groove 262. The first isolation groove 261 or the second isolation groove 262 may have a width ranging from 20 microns to 200 microns. At least one outer groove 27 is formed on the first electrode layer 21 inside the first isolation groove 261 and the second isolation groove 262. The outer groove 27 may have a width ranging from 20 microns to 200 microns. According to FIG. 2A, after the interlayer 25 is formed, a cutting groove 29 may be further formed thereon to obstruct the conductivity of the interlayer 25, and thus eliminate problems of electric leakage or short-circuit faults during an edge isolating process of the stacked-layered thin film solar cell 2, thereby providing enhanced insulating efficiency while not increasing overall manufacturing costs. Alternatively, the cutting groove 29 can extend downward further to remove the first photoconductive layer 23, as shown in FIG. 2C. Therein, the cutting groove 29 may be formed inside the first isolation groove 261, or may be formed inside or outside the outer groove 27, or may overlap the outer groove 27, wherein the cutting groove 29 is preferably formed outside the outer groove 27. The cutting groove 29 may have a width ranging from 20 microns to 200 microns.

The first isolation groove 261, the second isolation groove 262 and the cutting groove 29 may be formed by a laser scribing process, a wet etching process, or a dry etching process.

The first electrode layer 21 may be formed on the substrate 20 by a sputtering process, an APCVD (Atmospheric Pressure Chemical Vapor Deposition) process, or a LPCVD (Low Pressure Chemical Vapor Deposition) process. The first electrode layer 21 may have a single-layer structure or a multi-layer structure and may be made of a TCO (Transparent Conductive Oxide) comprising SnO2, ITO, ZnO, AZO, GZO or IZO. The first electrode layer 21 may further comprise a metal layer made of Ag, Al, Cr, Ti, Ni or Au.

The first photoconductive layer 23 may be formed on the first electrode layer 21 by a deposit process and made of single-crystal Si, multi-crystal Si, non-crystal Si, micro-crystal Si, Ge, SiGe and SiC. The interlayer 25 may be formed on the first photoconductive layer 23 by a deposit process and made of a material selected from TO, ITO, ZnO, AZO, GZO and IZO. The second photoconductive layer 24 may also be formed on the interlayer 25 by a deposit process with single-crystal Si, multi-crystal Si, non-crystal Si, micro-crystal Si, Ge, SiGe and SiC.

The second electrode layer 22 may be formed on the second photoconductive layer 24 by a sputtering process, or a PVD (Physical Vapor Deposition) process. The second electrode layer 22 may have a single-layer structure or a multi-layer structure and may be made of a TCO (Transparent Conductive Oxide) comprising SnO2, ITO, ZnO, AZO, GZO or IZO. The second electrode layer 22 may further comprise a metal layer made of Ag, Al, Cr, Ti, Ni, Au or an alloy of any of the above materials.

The present further provides a second preferred embodiment. Therein, a manufacturing method of a stacked-layered thin film solar cell 2, for improving edge isolation of the stacked-layered thin film solar cell 2 and eliminating short-circuit faults, comprises steps of:

(1) providing a substrate 20, a first electrode layer 21, a first photoconductive layer 23, an interlayer 25, a second photoconductive layer 24, and a second electrode layer 22 in a series stacked structure;

(2) providing a first isolation groove 261 and a second isolation groove 262 on at least two borders of the second electrode layer 22, wherein a first isolation groove 261 and a second isolation groove 262 are outside a projection zone of the unit cells 212 and extending downward to remove the first photoconductive layer 23 while the first isolation groove 261 is parallel with the unit cells 212 and vertical to the second isolation groove 262;

(3) providing at least one outer groove 27 on the first electrode layer 21 inside the first isolation groove 261 and the second isolation groove 262; and

(4) providing at least one cutting groove 29 inside the first isolation groove 261 on the interlayer 25.

In the manufacturing method of the present invention, the substrate 20, the first electrode layer 21, the first photoconductive layer 23, the interlayer 25, the second photoconductive layer 24, and the second electrode layer 22, the first isolation groove 261, the second isolation groove 262, the outer groove 27 and the cutting groove 29 share the same features of their resemblances described in the first embodiment.

Although the particular embodiments of the invention have been described in detail for purposes of illustration, it will be understood by one of ordinary skill in the art that numerous variations will be possible to the disclosed embodiments without going outside the scope of the invention as disclosed in the claims.

What is claimed is:

1. A stacked-layered thin film solar cell, with a plurality of unit cells comprising a substrate, a first electrode layer, a first photoconductive layer, an interlayer, a second photoconductive layer, and a second electrode layer in a series stacked structure, and being characterized in that
first isolation grooves are formed on two borders of the second electrode layer, wherein the first isolation grooves are outside a projection zone of the unit cells and are extending downward to remove the first photoconductive layer;
at least one outer groove is formed on the first electrode layer inside the first isolation groove; and
at least one cutting groove is formed on the interlayer inside the first isolation groove.

2. The stacked-layered thin film solar cell of claim 1, wherein second isolation grooves are further formed on two borders of the second electrode layer outside the projection zone of the unit cells and extending downward to remove the first photoconductive layer, in which either the first isolation grooves or the second isolation grooves are vertical to the unit cells.

3. The stacked-layered thin film solar cell of claim 2, wherein the first isolation grooves and the second isolation grooves are further extending downward to remove the first electrode layer.

4. The stacked-layered thin film solar cell of claim 1, wherein the cutting groove is further extending downward to remove the first photoconductive layer.

5. The stacked-layered thin film solar cell of claim 1, wherein the cutting groove is inside the outer groove.

6. The stacked-layered thin film solar cell of claim 1, wherein the cutting groove is outside the outer groove.

7. The stacked-layered thin film solar cell of claim 1, wherein the cutting groove overlaps the outer groove.

8. The stacked-layered thin film solar cell of claim 2, wherein the first isolation groove, the second isolation groove, and the cutting groove are made by a laser scribing process.

9. The stacked-layered thin film solar cell of claim 2, wherein the first isolation groove, the second isolation groove, and the cutting groove are made by a process selected from a group consisting of a wet etching process and a dry etching process.

10. The stacked-layered thin film solar cell of claim 2, wherein the substrate is made of a transparent material.

11. The stacked-layered thin film solar cell of claim 2, wherein the first electrode layer is made of a TCO (Transparent Conductive Oxide) of a material selected from a group consisting of SnO2, ITO, ZnO, AZO, GZO and IZO and the second electrode layer further comprises a metal layer made of a material selected from a group consisting of Ag, Al, Cr, Ti, Ni and Au.

12. The stacked-layered thin film solar cell of claim 2, wherein the second electrode layer further comprises a TCO (Transparent Conductive Oxide), which is made of a material selected from a group consisting of SnO2, ITO, ZnO, AZO, GZO and IZO.

13. The stacked-layered thin film solar cell of claim 2, wherein the second electrode layer is made of a TCO (Transparent Conductive Oxide) of a material selected from a group consisting of SnO2, ITO, ZnO, AZO, GZO and IZO and the first electrode layer further comprises a metal layer made of a material selected from a group consisting of Ag, Al, Cr, Ti, Ni and Au.

14. The stacked-layered thin film solar cell of claim 2, wherein the first photoconductive layer is made of a martial selected from a group consisting of single-crystal Si, multi-crystal Si, non-crystal Si, micro-crystal Si, Ge, SiGe and SiC.

15. The stacked-layered thin film solar cell of claim 2, wherein the interlayer is made of a martial selected from a group consisting of TO, ITO, ZnO, AZO, GZO and IZO.

16. The stacked-layered thin film solar cell of claim 2, wherein the second photoconductive layer is made of a martial selected from a group consisting of single-crystal Si, multi-crystal Si, non-crystal Si, micro-crystal Si, Ge, SiGe and SiC.

17. A manufacturing method of a stacked-layered thin film solar cell, comprising:
providing a substrate;
forming a first electrode layer on the substrate;
forming at least one outer groove on the first electrode layer;
forming a first photoconductive layer on the first electrode layer;
forming an interlayer on the first photoconductive layer;
forming at least one cutting groove on the interlayer;
forming a second photoconductive layer on the interlayer;
forming a second electrode layer on the second photoconductive layer; and
forming first isolation grooves at two borders of the second electrode layer outside the outer groove and the cutting groove, wherein the first isolation grooves are extending downward to remove the first photoconductive layer.

18. The manufacturing method of claim 17, wherein second isolation grooves are further formed on two borders of the second electrode layer outside a projection zone of the unit cells and extending downward to remove the first photoconductive layer, in which the second isolation grooves are vertical to the first isolation grooves while either the first isolation grooves or the second isolation grooves are vertical to the unit cells.

19. The manufacturing method of claim 18, wherein the first isolation grooves and the second isolation grooves are further extending downward to remove the first electrode layer.

20. The manufacturing method of claim 17, wherein the cutting groove is further extending downward to remove the first photoconductive layer.
